(19) United States
(12) Patent Application Publication
(10) Pub. No.: US 2016/0179733 A1
(43) Pub. Date: Jun. 23, 2016

(54) TWO-PART ELECTRICAL CONNECTOR

(71) Applicant: Intel Corporation, Santa Clara, CA (US)

(72) Inventors: Shaowu Huang, Seattle, WA (US); Beom-Taek Lee, Mountain View, CA (US)

(73) Assignee: Intel Corporation, Santa Clara, CA (US)

(21) Appl. No.: 14/580,950

(22) Filed: Dec. 23, 2014

(51) Int. Cl. G06F 13/40; H01R 12/70; G06F 13/42; G06F 1/18; G06F 13/28; H01R 13/502; H05K 3/32

(52) U.S. Cl. CPC G06F 13/4072; H01R 13/502; H01R 12/7076; H05K 3/32; G06F 1/183; G06F 13/28; G06F 13/4282

(57) ABSTRACT

A two-part electrical connector includes a bottom connector and a top connector. The bottom connector includes a set of electrical contacts, at least one of which has a relatively short effective electrical stub length. The bottom connector may be mounted on a memory bus that also includes a standard memory receiver. In such a system, when driving by a memory bus, the bottom connector generates signal reflections that are significantly reduced compared to conventional systems.

### TECHNICAL FIELD

The disclosed technology relates generally to memory systems, and, more particularly, to the physical configuration of memory systems having increased performance over present systems.

### BACKGROUND

Motherboards are generally produced and sold without main memory attached. Instead, computer memory is typically added when a computer system is configured or built for later sale. Modern computer memory is connected to the motherboard by inserting a memory module, such as a Dual In-Line Memory Module (DIMM) into a receiver known as a DIMM connector or DIMM slot. Common DIMM connectors accommodate DIMMs having between 72 and 288 pins, depending on the type of memory being added to the memory board. Double Data Rate (DDR) memory channels in motherboards may have as few as one DIMM connector, but typically have 2, 3, or 4 DIMM connectors. Additionally, there may be multiple DDR channels on a single motherboard, each having multiple DIMM connectors.

Computer manufacturers or consumers oftentimes populate only a single DIMM connector in a given memory channel with memory, at least initially, leaving one or more slots available for later memory expansion. When empty DIMM connectors are present on a motherboard, or other type of board, performance suffers. For example, FIG. 1 illustrates memory signals sent from a Central Processing Unit (CPU) to a memory module, DIMM 0, which is inserted into DIMM connector 0. DIMM Connector 1 is empty. In other words, no memory module is inserted into the DIMM connector 1. Because the input signal is coupled, through board wiring, memory bus, or other electrical connections, to both the DIMM Connector 0 and DIMM Connector 1, the input signal is routed to the desired DIMM connector 0 but is also routed to the empty DIMM connector 1. The DIMM Connector 1, by virtue of it being an empty connector, generates reflections back on the input signal on the memory bus, which hinders performance. More specifically, the empty DIMM connector 1 behaves electrically as a stub, or electrical dead-end, in the channel, and reflects electrical signals back on to the memory bus. These reflections causes phase mismatch in the transmission signals, induce mismatch impedance conditions, exacerbate the level of inter-symbol interference, increase harmful coupling, and amplify crosstalk. They also reduce signal quality in the form of reduced eye margins, which is a measure of signal quality.

Previous solutions to the reflections caused by empty DIMM connectors include making design tradeoffs on other portions of the channel to absorb or partially absorb the negative electrical impact. For instance, these solutions include using a resistive load board in the unused DIMM connector, running at slower speeds, and improving the electrical performance of other components, such as routing, vias, etc., in the high speed memory channel to compensate the empty connector effects. Each of these solutions brings higher cost, slow performance, or does not adequately address the problem of insertion loss.

### BRIEF DESCRIPTION OF THE DRAWINGS

Embodiments of the disclosed technology are illustrated by way of example, and not by way of limitation, in the drawings and in which like reference numerals refer to similar elements.

FIG. 1 is a block diagram illustrating conventional electrical reflections caused by an empty memory connector.

FIG. 2 is a cross-sectional diagram illustrating electrical length of internal connection wires within a conventional DIMM connector.

FIG. 3 is a graph illustrating insertion loss from an electrical simulation that models a conventional empty memory connector.

FIG. 4 is an exploded block diagram of a two-part electrical connector and its environment according to embodiments of the invention.

FIG. 5 is a side-view drawing of the bottom connector of the two-part electrical connector according to embodiments of the invention.

FIG. 6 is a graph illustrating insertion loss from an electrical model that models electrical performance of an empty two-part electrical connector according to embodiments of the invention.

FIG. 7 is a block diagram illustrating a conventional motherboard layout including a populated conventional memory connector and an empty conventional memory connector.

FIG. 8 is a block diagram illustrating a motherboard layout including a populated conventional memory connector and an empty two-part electrical connector according to embodiments of the invention.

FIG. 9 is a graph of various S-parameters from a simulation structured to model the system of FIG. 7.

FIG. 10 is a graph of various S-parameters from a simulation structured to model the system of FIG. 8.

FIG. 11 is a graph illustrating eye heights from simulations structured to model the systems of FIG. 7 and FIG. 8.

FIG. 12 is a graph illustrating eye widths from simulations structured to model the systems of FIG. 7 and FIG. 8.

FIG. 13 is a graph illustrating eye heights from simulations structured to model a fully populated version of the memory connectors illustrated in FIG. 7 and FIG. 8.

FIG. 14 is a graph illustrating eye widths from simulations structured to model a fully populated version of the memory connectors illustrated in FIG. 7 and FIG. 8.

### DETAILED DESCRIPTION

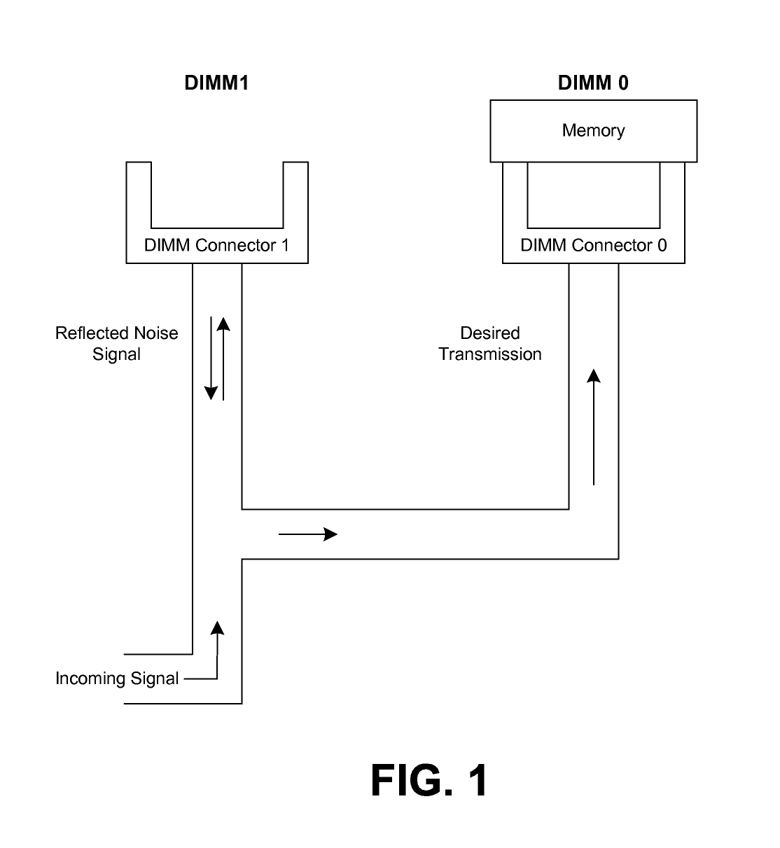

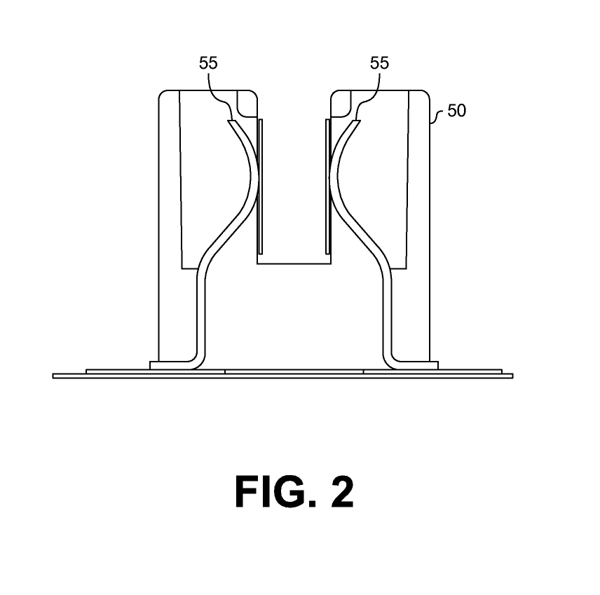

The particular reflections or resonant frequency of noise from an empty DIMM connector is directly related to the equivalent stub length of electrical lines in the empty connector. When the resonant frequency is low, the high speed signaling performance of the input signal can be seriously degraded by the reflected signals. Conventional DIMM connectors have long stub length, or electrical length, which leads to low resonant frequency. This, in turn, leads to decreased performance from the memory subsystem. FIG. 2 is a cross-sectional diagram of a conventional DIMM connector 50 that includes dozens or hundreds of internal connection wires 55, each connected to a different memory channel. DIMM connectors are often created to meet certain dimensional and electrical standards so that the connectors from various vendors are largely interchangeable. A trade organization and standard body named JEDEC Solid State Technology Association sets standard dimensions, mechanical, and electrical properties of many electrical components, including DIMM connectors, such as the DIMM connector 50 illustrated in FIG. 2. As mentioned above with reference to FIG. 1, the noise reflections in unterminated memory channels are largely caused by the equivalent electrical stub length of electrical connectors. The internal connection wires 55 illustrated in FIG. 2, made according to the JEDEC standard, are relatively long, with a length of over 6 mm, which accounts for all or a large portion of the equivalent stub length of the memory system.

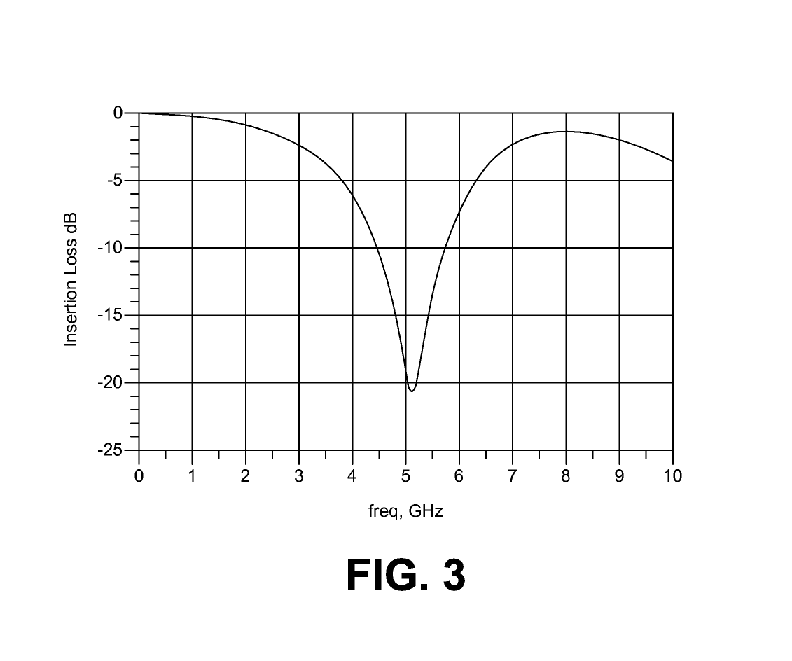

FIG. 3 is a graph illustrating insertion loss output generated by a high frequency structural simulator, set to simulate full wave electrical performance of the empty DIMM connector 50 of FIG. 2. The insertion loss illustrated by the graph is caused by the reflections from the DIMM connector 50 as set forth above. Note the substantial signal loss centered at approximately 5 GHz, which means that performance substantially decreases as the signals being carried on the memory bus approach 5 GHz. Since increasing the frequency of CPU-to-memory communications increases performance, and because present communication speeds are already over 2 GHz, system designers are approaching a substantial performance barrier with conventional DIMM connecters.

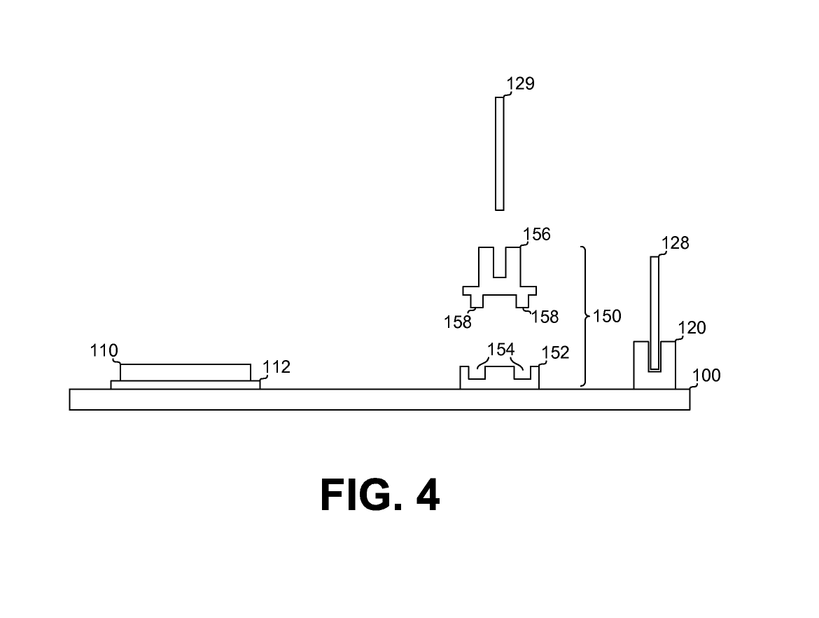

FIG. 4 is an exploded block diagram of a two-part electrical connector and its environment according to embodiments of the invention. A CPU 110 is coupled to a motherboard 100. The motherboard 100 is a multi-layer board having multiple electrical conduction layers running through it. The CPU 110 typically sits in an electrical socket 112 and is connected to the motherboard 100 through motherboard vias (not shown). The motherboard 100 connects the CPU 110 to a memory bus that includes the electrical connections within the motherboard. The memory bus is also attached, through a motherboard pinfield (not shown) to a DIMM connector 120 and a DIMM connector 150. The DIMM connector 120 is conventional, while the DIMM connector 150 is a two-part electrical connector. The DIMM connector 150 includes two pieces—a bottom DIMM connector, bottom part, bottom portion, or simply bottom connector 152, and a top DIMM connector, top part, top portion, or simply top connector 156. Often, as mentioned above, the memory system includes only a single DIMM populating a single DIMM connector. In the example illustrated in FIG. 3, a DIMM 128 populates the standard DIMM connector 120. If only one memory module is attached to the motherboard 100, then the memory module preferably populates the conventional DIMM connector 120. In other words, there is a performance benefit to leaving the low-profile DIMM connector 150 empty, as opposed to inserting the memory module in the low-profile DIMM connector 150 and leaving the standard DIMM connector 120 empty, as is described in detail below.

Still referring to FIG. 4, the low-profile DIMM connector 150 includes the bottom connector 152 and the top connector 156. The bottom connector 152 may be formed so that it that presents on the memory channel as a short stub. For example, recall from above that the standard DIMM connector had an electrical stub length of approximately 6 mm. The electrical stub length of the bottom connector 152 according to embodiments of the invention is between 1.5 and 3.0 mm, and, more preferably, is between 2.25 and 2.75 mm. Having this electrical stub length provides system benefits compared to conventional systems, as described in detail below.

The top connector 156 may be mechanically and electrically coupled to the bottom connector 152 by mechanically inserting it into the bottom connector 152. In more detail, the top connector 156 may include one or more projections 158 that are received by mechanical receivers 154 in the bottom connector 152. Within the mechanical receivers 154 and projections 158 may be spring-type electrical connectors or other electrical connectors that become electrically coupled to one another when the top connector 156 is inserted into the bottom connector 152. The mechanical receivers 154 and electrical connectors within them may be referred to individually or collectively as a mating structure of the bottom connector 152. Likewise, the projections 158 and electrical connectors attached to them may be referred to individually or collectively as a mating structure of the top connector 156. A memory module 129 may be inserted into the top connector 156. When the top connector 156 includes a memory module 129 and the top connector is inserted into the bottom connector 152, and electrical path exists between the bottom connector through the top connector to the memory module. Thus, the system illustrated in FIG. 4 may include one or two memory modules. If only one memory module is inserted, then it is preferably inserted into the conventional DIMM connector 120, while the bottom connector 152 remains empty, i.e., without either the top connector 156 or the memory module 129 coupled to it. If instead two memory modules are mounted on the motherboard 100, then one of the memory modules 128 in inserted into the conventional DIMM connector 120, while the second memory module 129 is inserted into the top connector portion 156 of the DIMM connector 150, which in turn is inserted into the bottom connector 152 portion of the DIMM connector 150.

In practical operation, the bottom connector 152 may be permanently soldered to motherboard 100, through a set of bus connectors. The top connector 156 is kept separately from the bottom connector, i.e., it is not plugged into the bottom connector, until such time when the user wishes to install additional memory. Then, the user plugs the top connector 156 into the bottom connector 152 to create a complete connector that can hold the memory module. Then the user plugs the memory module 129 into the top connector 156 to complete the electrical connections between the memory module 129, the connector 150, the motherboard 100, and the CPU 110.

In some embodiments the memory bus or memory channel can be implemented by the CPU 100 as illustrated in FIG. 4, or through expandable components, such as a memory buffer, Peripheral Component Interface Express (PCIe) devices, or a memory fabric, for example. High capacity memory can be implemented through such expandable components.

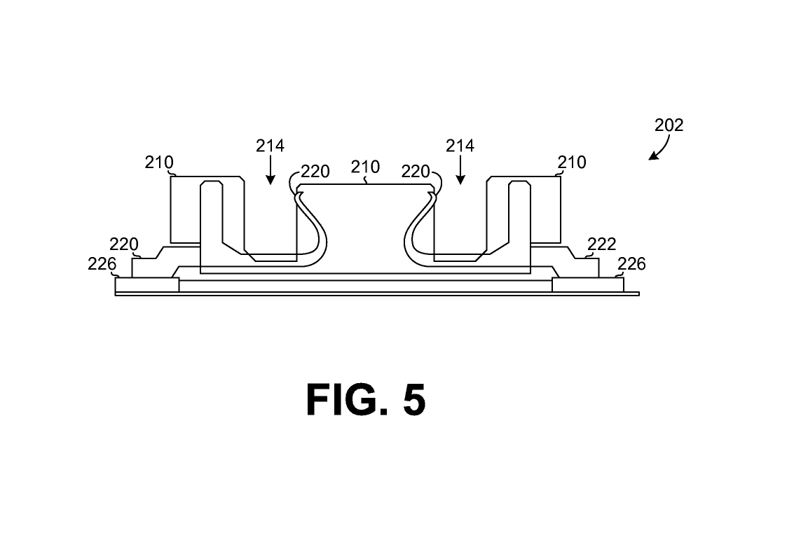

FIG. 5 is a side-view drawing of a bottom connector 202 of a two-part electrical connector according to embodiments of the invention. The bottom connector 202 may be an example of the bottom connector 152 of the two-part electrical connector 150 illustrated in FIG. 4 above. The bottom connector 202 includes body portions 210, which are typically made from plastic or other durable material. The body 210 preferably includes two slots 214 which receive a mating surface of an upper portion of the low-profile memory connector (not shown in FIG. 5), as described above. Electrical connectors 220 within the slots 214 provide electrical connection to the top connector when the top connector is inserted within the slots. One or both of the electrical connectors 220 or the slots 214 may be referred to as a mating structure. There are typically as many electrical connectors 220 in the bottom connector 202 as there are corresponding connectors on memory modules. Typical modules include between 72 and 288 connector pins, although embodiments of the invention may use any number of pins depending on implementation. The electrical connectors 220 are also electrically connected to extension legs 222, which, further in turn, are electrically coupled to pads 226. The pads 226 may be part of or connected to the memory channels on the motherboard, such as the motherboard 100 described in FIG. 4, or may be pads that are further connected to the motherboard 100 though another connector (not shown). These pads 226 may be part of a set of bus connectors that electrically couple the bottom connector 202 to the memory bus, or the pads 226 may be electrically coupled to such bus connectors. The bottom connector 202 of the two-part electrical connector may be embodied by or similar to an existing design for what is known as a board-to-board connector or connector-to-connector type connector.

As described above, the equivalent stub length of the electrical connectors 220 of an empty connector 202 determines the resonant frequency of the reflected signals reflected back on the memory bus. When the resonant frequency is low, such as in the case of conventional DIMM connectors, which have a long stub length, the high speed signaling performance can be seriously degraded by the reflected signals. This was previously described with reference to FIGS. 2 and 3. Conversely, the bottom connectors of two-part electrical connectors according to embodiments of the invention have a much shorter equivalent stub length compared to the conventional DIMM connectors, thus the resonant frequency is much higher. More specifically, the actual length of the electrical connectors 220 contribute directly to the equivalent stub length of the bottom connector 202. Thus, because the actual length of the electrical connectors 220 of the bottom connector are between 1.0 and 3.0 mm, this also creates an effective stub length of the bottom connector 202 between 1.0 and 3 mm, as the length of the electrical connectors 220 account for all or nearly all of the electrical stub length of the bottom connector 202.

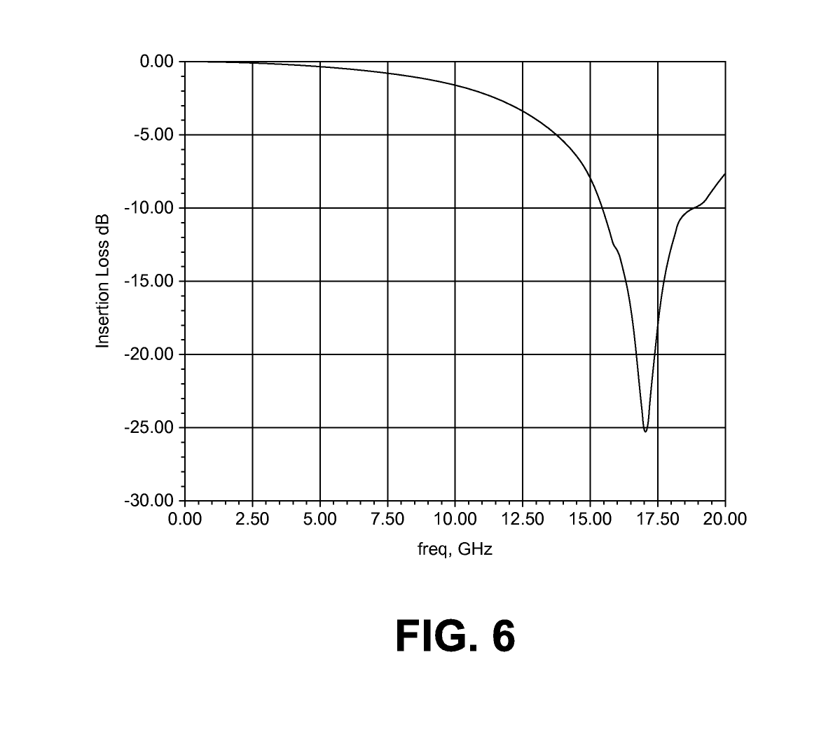

FIG. 6 is a graph illustrating insertion loss from a high frequency structural simulator set to simulate full wave electrical performance of an empty two-part electrical connector according to embodiments of the invention. As with the insertion loss graph illustrated in FIG. 3, the insertion loss illustrated by the graph in FIG. 6 is caused by the reflections from the bottom connector of a two-part electrical connector, such as the two-part electrical connector illustrated in FIGS. 4 and 5. Having a shorter electrical stub length or effective stub length of the bottom connector increases performance of the system. With reference to FIGS. 6 and 3, the signal loss caused by reflections in the two-part electrical connector according to embodiments of the invention is centered at a much higher frequency than the standard memory connector. More specifically, insertion losses due to these effects are not materially present until the data transmission speed of the memory bus is clocked at approximately 17 GHz, which is a substantial increase from the conventional solution. The difference between the insertion losses illustrated in FIGS. 3 and 6 are directly related to effective stub lengths of unpopulated memory connectors. In other words, reducing the actual or effective stub length of electrical connectors, such as in the bottom connector of the two-part connector described above, increases performance. Having a bottom connector with a stub length or effective stub length less than 3.0 mm causes the frequency at which the insertion loss becomes prominent to be raised by a significant amount, from approximately 5 GHz in FIG. 3 to approximately 17 GHz in FIG. 6.

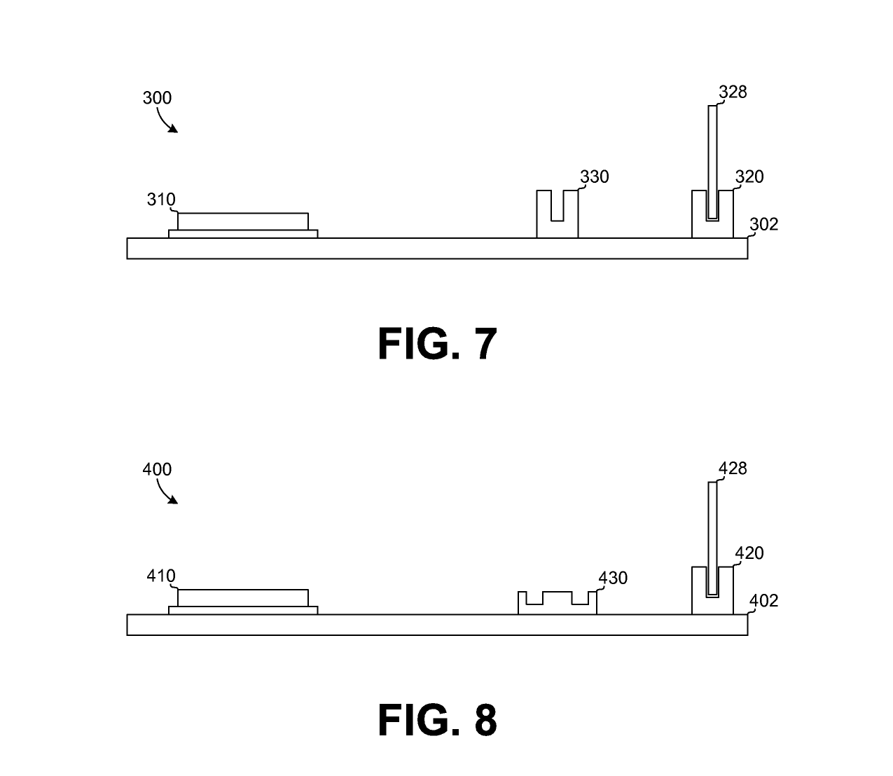

FIG. 7 is a block diagram illustrating a system 300 having a conventional motherboard layout including a populated conventional memory connector and an empty conventional memory connector. More particularly, in the system 300, a motherboard 302 includes a CPU 310 that is coupled to two conventional memory connectors, a first conventional connector 320 and a second conventional connector 330. A memory module 328 populates the first conventional connector 320 while the second conventional connector 330 remains empty. This system may be abbreviated as a 2SPC/1DPC system. The 2SPC label indicates that there are two slots per memory channel, i.e., that there are two slots, one each, in memory connectors 320 and 330. The 1DPC label indicates that there is only 1 DIMM inserted in the channel, i.e., the DIMM 328 inserted into the conventional connector 320.

FIG. 8 is a block diagram illustrating a system 400 having a motherboard layout including a populated conventional memory connector and an empty two-part electrical connector according to embodiments of the invention. More particularly, in system 400, a motherboard 402 includes a CPU 410 that is coupled to a conventional connector 420 and a two-part electrical connector according to embodiments of the invention. Only a lower part 430 of the two-part electrical connector is illustrated in FIG. 8, since the two-part electrical connector is empty in this configuration. A memory module 428 populates the conventional connector 420 while the lower part 430 remains empty. The system of FIG. 8 is also a 2SPC/1DPC system.

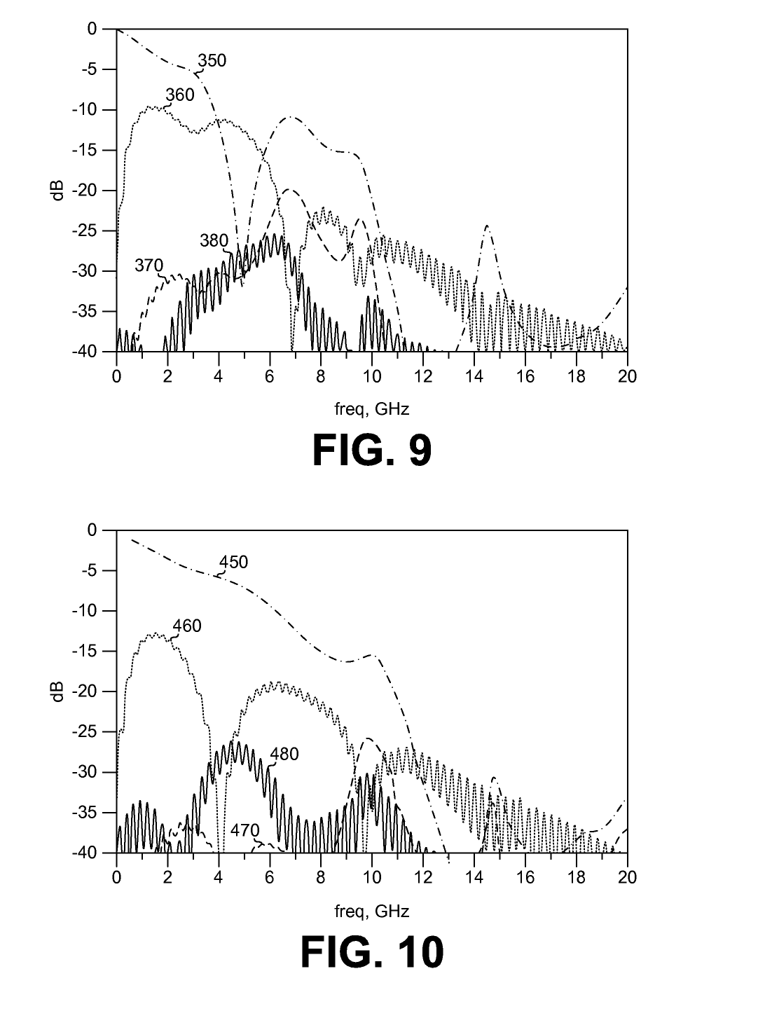

FIG. 9 is a graph of various S-parameters from a simulation structured to model the system 300 of FIG. 7, while FIG. 10 is a graph of various S-parameters from a simulation structured to model the system 400 of FIG. 8. As seen in FIG. 9, a data graph 350 illustrates insertion loss of the system 300 of FIG. 7. The insertion loss in the data graph 350 includes a large resonant dip at 5 GHz, illustrated previously in FIG. 3, which is caused by the empty second conventional connector 330 of the system 300 (FIG. 7). Also as addressed above, this insertion loss creates phase mismatch in the transmission signals, induces mismatch impedance conditions, exacerbates the level of inter-symbol interference, increases harmful coupling, and amplifies crosstalk.

In comparison to the data graph 350 that shows insertion loss of the system 300 of FIG. 7, a data graph 450 in FIG. 9 shows insertion loss of the system 400 of FIG. 8. The data graph 450 has no resonant dip below 10 GHz. Recall that the difference between the systems 300 and 400 of FIGS. 6 and 7 is that the system 400 includes a bottom connector 430 of the two-part electrical connector according to embodiments of the invention rather than the conventional connector 330. Thus, pushing out the resonant dip to above 10 GHz allows much better memory bus performance for transferring data between a CPU in situations where one or more memory connectors in a computing system are not fully populated with memory modules.

FIGS. 9 and 10 also include graphs of return loss of the systems of FIGS. 7 and 8, indicated in FIGS. 9 and 10 by graphs 360 and 460, respectively. The system 400 that includes the two-part electrical connector has a much lower return loss, i.e., loss of power due to reflections. In other words, the standard system 300 of FIG. 7 that includes a standard DIMM connector 330 generates more return loss when it is not fully populated than does the system 400 of FIG. 8 that includes the bottom connector 430 of the two-part electrical connector. As addressed above, having a lower return loss provides a system that has better data transfer characteristics.

Also illustrated in FIGS. 9 and 10 are graphs for Far-End Cross Talk (FEXT) and Near-End Cross Talk (NEXT). FEXT is a measure of how much a signal on a first line affects the signal on an adjacent line, typically by generating noise on the adjacent line. For instance, data placed on memory channel 0 may affect the fidelity of the data on memory channel 1 by the data on channel 1 being influenced by signals on channel 0. The measure of how much one channel influences a neighboring channel is measured as noise, and is reflected in the FEXT, which as can be seen on graphs 370 and 470, is much better in the inventive system 400 of FIG. 8 than the conventional system 300 of FIG. 7. Finally, the NEXT measurement measures near-end cross talk, which is a measure of how data on one channel creates noise on an adjacent channel near the beginning of the channel rather than the end, as the case with FEXT. As illustrated in the graphs 380 and 480, there is also less noise caused by NEXT in the inventive system 400 of FIG. 8 than the conventional system 300 of FIG. 7.

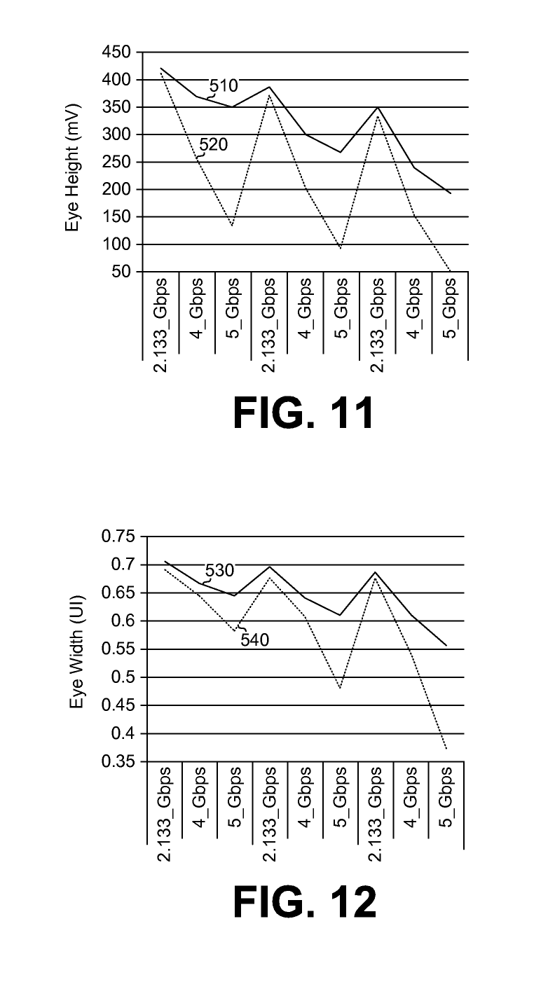

FIG. 11 includes graphs illustrating eye heights from simulations structured to model the systems of FIG. 7 and FIG. 8, while FIG. 12 includes graphs illustrating eye widths from the same systems. Graphs in FIGS. 11 and 12 each include multiple data points. First, simulations were run for various routing lengths to simulate multiple potential memory channel lengths. For example, simulations were run at 5 inches, 10 inches, and 15 inches. These channel length possibilities cover a large percentage of potential memory systems that can benefit from embodiments of the invention, and illustrate that embodiments of the invention have widespread use. Additionally, eye height data was collected at multiple data transmission data rates. For example, data was collected at 2.333 Gbps, 4 Gbps, and 5 Gbps for all of the simulated memory channel lengths mentioned above. With reference to graphs 510 and 520 of FIG. 11, the average eye height of the conventional memory system 300 illustrated in FIG. 7 is illustrated as graph 520, while the average eye height of the memory system 400 in FIG. 8, including the two-part electrical connector according to embodiments of the invention, is illustrated as graph 510. The eye height measurement of FIG. 11 comes from an eye diagram oscilloscope display that is used to measure signal distortion caused by channel noise and intersymbol interference. In an eye diagram, a higher eye height corresponds to better channel performance. As illustrated in FIG. 11, the graph 510 shows that the system 400 of FIG. 8 has significantly higher eye heights than does the graph 520, which presents data from the conventional system 300 of FIG. 7.

FIG. 12 is similar to FIG. 11, except that graph 530 shows that the system 400 of FIG. 8, which includes embodiments of the invention, has larger eye widths than does the graph 540, which presents data from the conventional system 300 of FIG. 7. Having a greater eye width corresponds to better channel performance, as it indicates that there is additional time at the receiver to accurately decode data placed on the data channel. Increasing the eye width margin is one of the most pressing performance limitations with systems that include Double Data Rate (DDR) memory topologies with empty connectors.

The above graphs in FIGS. 9, 10, 11, and 12 show how having a non-populated, two-part electrical connector in memory systems rather than a non-populated, conventional memory connector provides performance gains in almost every data signal measurement category due to the reduced reflections placed on the memory channels. These performance gains include reduced intersymbol interference, a reduction in timing jitter, reduced noise, increased margins of signal fidelity as measured by eye heights and widths, and improved signal integrity.

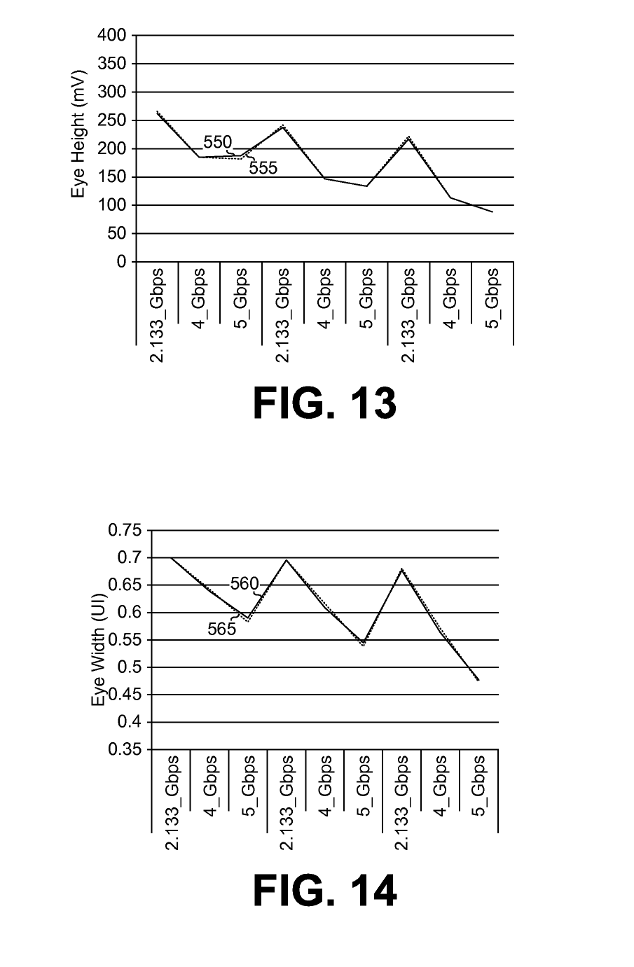

FIGS. 13 and 14 are similar to FIGS. 11 and 12, except FIGS. 13 and 14 are simulations for the systems 300 and 400 of FIGS. 6 and 7, respectively, that have fully populated memory channels. In other words, FIG. 13 includes graphs that simulate the system 300 of FIG. 7 that includes a memory module 328 in both the first conventional connector 320 and the second conventional connector 330. Similarly, FIG. 14 includes graphs that simulate the system 400 of FIG. 8 that includes a memory module 428 both the conventional connector 420 and the two-part electrical connector. Of course, in addition to the memory module 428, the matching, upper-part of the illustrated lower portion 430 would also be connected to the lower part. In other words, for FIGS. 12 and 13, the simulations are systems that can be referred to as 2SPC/2DPC, i.e., two slots per channel and two DIMMS per channel.

With reference to FIG. 13, graph 550 illustrates the average eye height for the system 300 of FIG. 7 that is fully populated with memory at the same channel lengths and bit rates as in FIG. 11. Similarly, graph 555 illustrates the average eye height for the system 400 of FIG. 8 that is fully populated with memory. Since the graphs 550 and 555 are nearly co-extensive, this means that the presence of the two-part electrical connector according to embodiments of the invention such as illustrated in FIG. 8 does not hinder performance when the two DIMM connectors are fully populated with memory as measured by average eye height. FIG. 14 similarly shows that the average eye width is also not affected by the presence of the two-part electrical connector according to embodiments of the invention, as illustrated in graphs 560 and 565.

The combination of FIGS. 10-14 together illustrate that the significant improvement in average eye height and eye width of the empty slot topologies enables them for running faster beyond fully populated topologies (2SPC/2DPC, 3SPC/3DPC).

Embodiments of the invention are applicable to any form of expandable memory configurations. Such systems include, for example, consumer electronics, desktop, mobile and enterprise markets. Embodiments of the invention may also be used in packaging technology, and electronic components technology, such as connectors.

Embodiments of the invention may provide potential to allow for more complex designs and higher data rate signaling on printed circuit boards with empty connectors, particularly for memory channel connectors. The gains provided by embodiments of the invention scale to frequencies much higher than current signaling rates of mainstream memory products, and could enable higher data rate signaling on future memory interfaces.

Embodiments of the invention include a two-part memory socket with a bottom connector and a top connector. The bottom connector includes a set of bus connectors structured to be electrically coupled to a memory bus, at least one mating structure, and a first set of electrical contacts. The a top connector includes a mating structure configured to mechanically interface with the at least one mating structure of the bottom connector, a second set of electrical contacts, and a receiving slot structured to receive a memory module. In some embodiments, when the mating structure of the top connector is mechanically interfaced with the at least one mating structure of the bottom connector, an electrical connection exists between the receiving slot and one or more of the set of bus connectors.

In some embodiments the electrical contacts in the first set of electrical contacts have an effective electrical stub length of less than approximately 3 mm, and more preferably between approximately 2.0 mm and 2.75 mm.

In some embodiments, the receiving slot in the top connector is structured to receive a Double Data Rate Double In-Line Memory Module (DDR DIMM).

Additional embodiments of the invention include a main board including a memory system. The main board includes a Central Processing Unit (CPU) mount, a memory bus electrically coupled to the CPU mount, a first DIMM connector structured to receive a memory module; and a second DIMM connector having a slot structured to receive a memory module. The second DIMM connector includes a bottom connector and a separable top connector. The bottom connector has bus connectors structured to be electrically coupled to the memory bus, and including a first set of electrical contacts. The top connector includes the slot structured to receive the memory module. In some embodiments the bottom connector comprises a mechanical interface structured to couple to a mechanical interface of the top connector. In some embodiments, when the top connector is coupled to the bottom connector, an electrical path is formed between the slot of the top connector and the bus connectors of the bottom connector. In some embodiments, the bottom connector comprises a set of electrical contacts in which at least one has an effective electrical stub length of less than approximately 3 mm, and more preferably, between 2.0 and 2.75 mm.

Yet further embodiments of the invention include a main board including a memory system. The main board includes a Central Processing Unit (CPU) mount, a memory bus electrically coupled to the CPU mount, a first DIMM connector structured to receive a memory module; and a two-part means having a slot structured to receive a memory module. The two-part means may include a bottom means and a separable top means. The bottom means has bus connectors structured to be electrically coupled to the memory bus, and including a first set of electrical contacts. The top means includes the slot structured to receive the memory module. In some embodiments the bottom means comprises an interface means structured to couple to a mechanical interface of the top connector. In some embodiments, when the top means is coupled to the bottom means, an electrical path is formed between the slot of the top means and the bus connectors of the bottom means. In some embodiments, the bottom means comprises a set of electrical contacts in which at least one has an effective electrical stub length of less than approximately 3 mm, and more preferably, between 2.0 and 2.75 mm.

Other embodiments include a method of making a main board that has a memory system. Such methods include forming a memory bus on the main board, attaching a first memory connector that is structured to receive a memory module to the memory bus of the main board, and attaching a bottom part of a two-part memory connector to the memory bus of the main board.

In some embodiments, attaching a bottom part of a two-part memory connector to the memory bus of the main board comprises attaching a bottom part of a two-part memory connector that includes a set of contacts at least one of which has an effective electrical stub length of less than approximately 3 mm, and more preferably between 2.0 and 2.75 mm.

Other methods include a method of sending data signals on a data bus. Such methods include generating data signals, driving the data bus with the signals to a first memory disposed in a first memory connector on the data bus, and at the same time as driving the data bus with the data signals to the first memory, driving the data bus with the data signals to a bottom connector of a two-part data connector that is mounted to the data bus. In some embodiments, the method further includes attaching a top connector to the bottom connector, and attaching a second memory to the top connector. In some methods attaching a top connector to the bottom connector comprises mechanically and electrically coupling the top connector to the bottom connector. In some embodiments the bottom part of the two-part memory connector includes a set of contacts at least one of which has an effective electrical stub length of less than approximately 3 mm, and more preferably between approximately 2.0 mm and 2.75 mm.

Although specific embodiments have been illustrated and described herein, it will be appreciated by those of ordinary skill in the art that a wide variety of alternate and/or equivalent implementations may be substituted for the specific embodiments shown and described without departing from the scope of the embodiments of the disclosed technology. This application is intended to cover any adaptations or variations of the embodiments illustrated and described herein. Therefore, it is manifestly intended that embodiments of the disclosed technology be limited only by the following claims and equivalents thereof.

What is claimed is:

1. A two-part electrical connector, comprising:
a bottom connector including:
a set of bus connectors structured to be electrically coupled to a memory bus,
at least one mating structure, and
a first set of electrical connectors; and
a top connector including:
a mating structure configured to mechanically interface with the at least one mating structure of the bottom connector,
a second set of electrical connectors, and
a receiving slot structured to receive a memory module.

2. The two-part electrical connector according to claim 1 in which, when the mating structure of the top connector is mechanically interfaced with the at least one mating structure of the bottom connector, an electrical connection exists between the receiving slot and one or more of the set of bus connectors.

3. The two-part electrical connector according to claim 1 in which at least one of the electrical connectors in the first set of electrical connectors has an electrical stub length of less than approximately 3 mm.

4. The two-part electrical connector according to claim 3 in which at least one of the electrical contacts in the first set of electrical connectors has an electrical stub length between approximately 2.25 mm and 2.75 mm.

5. The two-part electrical connector according to claim 1 in which the receiving slot in the top connector is structured to receive a Double Data Rate Double In-Line Memory Module (DDR DIMM).

6. A main board including a memory system, the main board comprising:
a Central Processing Unit (CPU) mount;
a memory bus electrically coupled to the CPU mount; and
a bottom connector of a two-part memory connector, the bottom connector including bus connectors structured to be electrically coupled to the memory bus, and including a first set of electrical contacts, and the bottom connector structured to receive a top connector that can accept a memory module within the top connector.

7. The main board including a memory system of claim 6 in which the bottom connector comprises a mechanical interface structured to couple to a mechanical interface of the top connector.

8. The main board including a memory system of claim 7 in which, when the top connector is coupled to the bottom connector, an electrical path is formed between the slot of the top connector and the bus connectors of the bottom connector.

9. The main board including a memory system of claim 6 in which the bottom connector comprises a set of electrical contacts and in which at least one of the electrical contacts in the set of electrical contacts has an effective electrical stub length of less than approximately 3 mm.

10. The main board including a memory system of claim 9 in which the at least one of the electrical contacts has an effective electrical stub length between approximately 2.25 mm and 2.75 mm.

11. A method of making a main board including a memory system, the method comprising:
forming a memory bus on the main board;
attaching a first memory connector that is structured to receive a memory module to the memory bus of the main board; and
attaching a bottom part of a two-part memory connector to the memory bus of the main board.

12. The method of making a main board including a memory system according to claim 11, in which attaching a bottom part of a two-part memory connector to the memory bus of the main board comprises attaching a bottom part of a two-part memory connector that includes a set of contacts at least one of which has an effective electrical stub length of less than approximately 3 mm.

13. The method of making a main board including a memory system according to claim 11, in which attaching a bottom part of a two-part memory connector to the memory bus of the main board comprises attaching a bottom part of a two-part memory connector that includes a set of contacts at least one of which has an effective electrical stub length of between approximately 2.25 mm and 2.75 mm.

14. The method of making a main board including a memory system according to claim 11, further comprising attaching a top part of the two-part memory connector to the bottom part.

15. The method of making a main board including a memory system according to claim 14, further comprising inserting a second memory module into the top part.

16. A method of sending data signals on a data bus, comprising:
generating data signals;
driving the data bus with the signals to a first memory disposed in a first memory connector on the data bus; and
at the same time as driving the data bus with the data signals to the first memory, driving the data bus with the data signals to a bottom connector of a two-part data connector that is mounted to the data bus.

17. The method of sending data signals on a data bus according to claim 16, further comprising:
attaching a top connector to the bottom connector; and
attaching a second memory to the top connector.

18. The method of sending data signals on a data bus according to claim 17, in which attaching a top connector to the bottom connector comprises mechanically and electrically coupling the top connector to the bottom connector.

19. The method of sending data signals on a data bus according to claim 16, in which the bottom part of the two-part memory connector includes a set of contacts at least one of which has an effective electrical stub length of less than approximately 3 mm.

20. The method of sending data signals on a data bus according to claim 19, in which the bottom part of the two-part memory connector includes a set of contacts at least one of which has an effective electrical stub length between approximately 2.25 mm and 2.75 mm.
